(19) United States
(12) Patent Application Publication
(10) Pub. No.: US 2007/0181903 A1
(43) Pub. Date: Aug. 9, 2007

(54) Semiconductor device manufacturing method and semiconductor device manufacturing apparatus

(75) Inventor: Hideya Takakura, Nara-ken (JP)

Correspondence Address: BIRCH STEWART KOLASCH & BIRCH, PO BOX 747, FALLS CHURCH, VA, 22040-0747, US

(73) Assignee: Sharp Kabushiki Kaisha

(21) Appl. No.: 11/703,679

(22) Filed: Feb. 8, 2007

(30) Foreign Application Priority Data
Feb. 9, 2006 (JP) 2006-032320
Nov. 24, 2006 (JP) 2006-317330

(51) Int. Cl. H01L 33/00; H01L 29/24

(52) U.S. Cl. 257/100

(57) ABSTRACT

A semiconductor device manufacturing method includes the steps of filling a cavity and a resin reservoir hole in a lower metal mold with a liquid-state resin, holding a semiconductor element between the lower metal mold and an upper metal mold, injecting the resin in the resin reservoir hole into the cavity to seal the semiconductor device with the resin. Thus, the semiconductor device having almost no voids and less material loss is manufactured with high accuracy.

### CROSS-REFERENCE TO RELATED APPLICATION

This nonprovisional application claims priority under 35 U.S.C. §119(a) on Patent Application No. 2006-032320 filed in Japan on 9 Feb. 2006 and Patent Application No. 2006-317300 filed in Japan on 24 Nov. 2006, the entire contents of which are incorporated herein by reference.

### BACKGROUND OF THE INVENTION

The present invention relates to a semiconductor device manufacturing method and a semiconductor device manufacturing apparatus.

In general, according to a method for manufacturing a semiconductor device, as shown in FIG. 15A, a semiconductor element 105 is manufactured by first bonding a semiconductor chip 102 to a lead frame 101 with an adhesive such as a silver paste. Then, as shown in FIG. 15B, the semiconductor chip 102 is connected to the lead frame 101 with a gold wire 103. Then, as shown in FIG. 15C, a semiconductor device 106 is manufactured by sealing the semiconductor element 105 with a resin 104. Subsequently, the semiconductor device 106 becomes a product after the steps of exterior plating, lead forming (lead frame processing), electrical characteristic inspection (measurement of various electric characteristics), marking, visual inspection and packing.

It is general to use a thermosetting resin such as epoxy resin and silicone resin as the resin 104. There are molding methods such as a transfer molding method and a casting molding method as a method for sealing with the resin 104.

In detail, when epoxy resin is used as the resin 104, the most general method of sealing with the epoxy resin is the transfer molding method. The transfer molding method has the steps of inserting and melting an epoxy resin, which is compression molded into a tablet form or an epoxy resin in a powder form, in a resin reservoir section called a pot maintained at high temperature and thereafter injecting the epoxy resin into a cavity formed at a metal mold maintained at high temperature through a runner with a pressure. After injecting the epoxy resin, the resin is held in a metal mold until the resin is completely hardened. Thereafter, the semiconductor device is taken out by vertically opening the metal mold and transferred to the subsequent step (refer to JP 2004-311748 A and JP 2002-94124 A).

As an example of a metal mold of the transfer molding, there is a one-pot type metal mold shown in FIG. 16A. The metal mold has one round pot portion 111 into which a resin is inserted, and has runner portions 112 that extend from the pot portion 111.

As another example of a metal mold of the transfer molding, there is a multi-pot type metal mold shown in FIG. 16B. The metal mold has a plurality of round pot portions 111 into which a resin is inserted, and has runner portions 112 that extend from the pot portions 111.

As still another example of a metal mold of the transfer molding, there is a cylindrical pot type metal mold shown in FIG. 16C. The metal mold has one cylindrical pot portion 111 into which a resin is inserted, and has runner portions 112 that extend from the pot portion 111.

The multi-pot type metal mold of FIG. 16B and the cylindrical pot type metal mold of FIG. 16C have a shortened resin path after melting in comparison with the one-pot type metal mold of FIG. 16A. Therefore they have an advantage that the molding conditions, such as a range of injection time in molding, become wider.

However, the resin needs to be subjected to compression molding into a mini tablet or a rod-like shape in the case of FIGS. 16B and 16C. Therefore, they have more faults in comparison with the normal tablet in the case of FIG. 16A, which causes a need to decrease variation in weight of the mini tablet. Also, the rod-shaped tablet is easy to break after being subjected to compression molding, which needs more care during conveyance.

When a liquid-state epoxy resin is used as the resin 104, the casting method shown in FIG. 17 or the potting method shown in FIG. 18 is employed as a method for sealing with the liquid-state epoxy resin.

In the casting method shown in FIG. 17, a semiconductor element 122 is set in a frame 121 prepared beforehand. The, a liquid-state resin 123 is injected into the frame 121. Thereafter the liquid-state resin 123 is heated for hardening.

In the potting method shown in FIG. 18, a semiconductor element 122 is set in a resin casing 124. Then, a liquid-state resin 123 is injected into the resin casing 124. Thereafter, the liquid-state resin 123 is heated for hardening.

When silicone resin is used for the resin 104, all the above-stated sealing methods can be considered as a method for sealing with the silicone resin. However, the potting method is most generally employed.

In recent years, for example, car electronics has been remarkably progressed in the forms of digital information equipment, AV equipment, intra-car networks, hybrid engines, electric cars, sensors for safety driving and so on. Under these circumstances, semiconductor devices used therefor are required to have high reliability and capability of enduring onboard environments. Specifically, the semiconductor devices are needed to cope with an ambient temperature of −40 to 125° C. for example.

In the case of using epoxy resin as a sealing resin, the epoxy resin has sufficiently tolerable characteristics in moisture resistance and so on. However, the epoxy resin has a disadvantage of being easily discolored by exposure to high temperature. In contrast to this, in the case of using silicone resin as a sealing resin, the silicone resin is hardly discolored even when it is exposed to high temperature.

Thus, it is necessary to use silicone resin for resin sealing in order to cope with high ambient temperature as in the case of car-onboard-use, especially, in an optical semiconductor device that has a function to transmit and receive light.

However, the above-described conventional semiconductor device manufacturing methods, specifically, the casting method and the potting method have the disadvantages of the low dimensional accuracy of a package, a high manufacturing cost as a consequence of much time and/or labor necessary for the manufacturing, and the frequent occurrence of voids as a consequence of the entry of air into a package.

In the transfer molding method, dimensional accuracy is improved. However, the transfer molding method has a disadvantage of increase in material cost due to superfluous resin generated in the runner portion and so on. Particularly, in the case where silicone resin is used as a sealing resin in order to manufacture a semiconductor device for the car-onboard use, the silicone resin is more expensive than the epoxy resin in unit price. Therefore, reduction in material loss is needed as much as possible.

### BRIEF SUMMARY OF THE INVENTION

An object of the present invention is to provide a semiconductor device manufacturing method with high accuracy, reduction in loss of material and less generation of voids in a way of sealing with liquid-state resin (particularly, silicone resin).

To achieve the above-mentioned object, the present invention provides a semiconductor device manufacturing method comprising:

a first step of filling a cavity formed in a lower metal mold and a resin reservoir hole formed in the lower metal mold and connected to the cavity with a liquid-state resin;

a second step of holding a semiconductor element between the lower metal mold and an upper metal mold; and

a third step of sealing the semiconductor element with the resin by injecting the resin of the resin reservoir hole into the cavity.

According to the semiconductor device manufacturing method of the present invention, unlike the potting method and the transfer molding method, it is possible to manufacture a semiconductor device with a little loss of material and excellent quality at low cost. Particularly, the loss of material can be further reduced when silicone resin is used as the resin to manufacture the semiconductor device for the car-onboard use. This is because the cavity and the resin reservoir hole in the lower metal mold are filled with the liquid-state resin, the semiconductor element is held between the lower metal mold and the upper metal mold, and the resin in the resin reservoir hole is injected into the cavity, so as to seal the semiconductor element with the resin.

In one embodiment of the present invention, the first step comprises placing a filling jig on the lower metal mold in such a way that a resin injection hole, which is formed in the filling jig and filled with the resin, is aligned with the cavity of the lower metal mold; and filling the cavity and the resin reservoir hole with the resin through the resin injection hole by opening a gate section formed in the filling jig to close or open the resin injection hole.

According to the embodiment, the cavity and the resin reservoir hole can be filled simply and reliably with the liquid-state resin because the cavity and the resin reservoir hole are filled with the liquid-state resin from the filling jig.

In one embodiment of the present invention, the first step comprises placing a tube extending from a resin feeder filled with the resin on the lower metal mold in such a way that an opening of the tube is aligned with the cavity of the lower metal mold; and filling the cavity and the resin reservoir hole with the resin through the opening of the tube via the tube from the resin feeder.

According to the embodiment, the cavity and the resin reservoir hole can be filled simply and reliably with the liquid-state resin because the cavity and the resin reservoir hole are filled with the liquid-state resin from the resin feeder via the tube.

In one embodiment of the present invention, the third step comprises injecting the resin of the resin reservoir hole into the cavity by extruding the resin into the cavity with use of an injection member moving in the resin reservoir hole; and pushing the semiconductor element sealed with the resin out of the lower metal mold with use of the injection member after the resin is hardened.

According to the embodiment, the resin is injected into the cavity by being extruded into the cavity with use of the injection member, and also the semiconductor element sealed with the resin is pushed out of the lower metal mold with use of the injection member. Thus, the semiconductor device can be manufactured swiftly and efficiently because the injection member is used not only as a plunger that extrudes the resin from the resin reservoir hole, but also as an ejector pin that pushes the semiconductor element out of the lower metal mold.

In one embodiment of the present invention, The semiconductor device manufacturing method as set forth in claim 1, wherein

the third step comprises:

injecting the resin of the resin reservoir hole into the cavity by extruding the resin into the cavity with use of an injection member moving in the resin reservoir hole; and

forming a lens portion of the hardened resin by pressurizing the resin during a hardening process with use of an end face formed in a lens-like shape of the injection member.

According to the embodiment, the lens portion can be formed swiftly and simply out of the resin because the lens portion of the hardened resin is formed by pressurizing the resin during hardening the resin with use of the end face of the injection member, which face is formed into the lens-like shape.

The present invention also provides a semiconductor device manufacturing apparatus comprising:

a lower metal mold having a cavity and a resin reservoir hole directly connected to the cavity;

an upper metal mold relatively coming close to or away from the lower metal mold and holding a semiconductor element together with the lower metal mold;

a filling device filling the cavity and the resin reservoir hole in the lower metal mold with a liquid-state resin; and

an injection member placed in the resin reservoir hole so as to reciprocate in the resin reservoir hole and injecting the resin of the resin reservoir hole into the cavity by extruding the resin into the cavity with use of the injection member.

According to the semiconductor device manufacturing apparatus of the present invention, the apparatus includes the lower metal mold that has the cavity and the resin reservoir hole, the upper metal mold that holds the semiconductor element with the lower metal mold, the filling device that fills the cavity and the resin reservoir hole in the lower metal mold with the liquid-state resin, and the injection member that injects the resin in the resin reservoir hole into the cavity. Therefore, the semiconductor element is sealed with the resin by filling the cavity and the resin reservoir hole of the lower metal mold with the liquid-state resin, holding the semiconductor element by the lower and upper metal molds and then injecting the resin of the resin reservoir hole into the cavity by the injection member.

Therefore, unlike the potting method and the transfer molding method, a semiconductor device can be manufactured with less loss of material and excellent quality at low cost. Particularly, the loss of material can be further reduced when silicone resin is used as the resin to manufacture the semiconductor device for the car-onboard use.

In one embodiment of the present invention, The semiconductor device manufacturing apparatus as set forth in claim 6, wherein

an end face of the injection member, which end face is placed on a side of the cavity in the lower metal mold, is formed into a lens-like shape.

According to the embodiment, since the end face of the injection member on the side of the cavity in the lower metal mold is formed into a lens-like shape, it is required to polish only the end face of the injection member but not the whole of the metal molds. This leads to cost reductions of the metal molds. Moreover, the dimensions of the lens can also be easily changed since the injection member can easily be replaced.

In one embodiment of the present invention, The semiconductor device manufacturing method as set forth in claim 1, wherein

the first step comprises:

placing the filling jig on the lower metal mold in such a way that a resin injection hole, which is formed in the filling jig and filled with the resin, is aligned with the cavity of the lower metal mold; and

filling the cavity and the resin reservoir hole with the resin through the resin injection hole by opening a gate section formed in the filling jig to close or open the resin injection hole and by moving an injection member, which is placed in the upper metal mold, in the resin injection hole of the filling jig.

According to the embodiment, the cavity and the resin reservoir hole can be filled simply and reliably with the liquid-state resin because the cavity and the resin reservoir hole are filled with the liquid-state resin from the filling jig by the injection member placed at the upper metal mold.

In one embodiment of the present invention, The semiconductor device manufacturing method as set forth in claim 8, wherein,

a lens portion of the hardened resin is formed by pressurizing the resin during hardening the resin by using an end face of the injection member placed in the upper metal mold, which end face is formed into a lens-like shape.

According to the embodiment, the lens portion can be formed swiftly and easily of the resin because the lens portion of the hardened resin is formed by pressurizing the resin during hardening the resin by using the end face of the injection member placed in the upper metal mold, which end face is formed in the lens-like shape.

In one embodiment of the present invention, The semiconductor device manufacturing method as set forth in claim 8, wherein

the semiconductor element sealed with the resin is pushed out of the cavity formed in the lower metal mold by using the injection member placed in the upper metal mold after the resin is hardened.

According to the embodiment, the semiconductor element sealed with the resin is pushed out of the cavity formed in the lower metal mold by using the injection member placed in the upper metal mold. Therefore, the semiconductor device can be manufactured swiftly and efficiently by using the injection member not only as a plunger for extruding the resin from the filling jig but also as an ejector pin for pushing the semiconductor element out of the lower metal mold.

In one embodiment of the present invention, The semiconductor device manufacturing method as set forth in claim 2, wherein

a hole of the gate section of the filling jig, via which the resin passes when the lower metal mold is filled with the resin through the resin injection hole of the filling jig, is tapered in such a way that the hole gradually decreases in diameter toward the lower metal mold.

According to the embodiment, the lower metal mold can be smoothly filled with the liquid-state resin since the hole of the gate section of the filling jig is tapered.

In one embodiment of the present invention, The semiconductor device manufacturing method as set forth in claim 1, wherein

the third step comprises:

injecting the resin of the resin reservoir hole into the cavity by extruding the resin into the cavity with use of an injection member moving in the resin reservoir hole;

retreating the injection member from a side of the cavity after the resin is hardened; and

pushing the semiconductor element sealed with the resin out of the lower metal mold by discharging air from the resin reservoir hole toward the cavity.

According to the embodiment, the semiconductor device can easily be taken out of the lower metal mold because the semiconductor element sealed with the resin is pushed out of the lower metal mold by discharging air from the resin reservoir hole toward the cavity.

In one embodiment of the present invention, The semiconductor device manufacturing apparatus as set forth in claim 6, wherein

an outer periphery of a bottom of the cavity coincides in shape with an inner periphery of the resin reservoir hole; and

an outer periphery of an end face of the injection member on a side of the cavity coincides in shape with the inner periphery of the resin reservoir hole.

According to the embodiment, the outer periphery of the bottom of the cavity coincides in shape with the inner periphery of the resin reservoir hole, and also the outer periphery of the end face of the injection member coincides in shape with the inner periphery of the resin reservoir hole. Therefore, the outer periphery of the bottom of the cavity coincides in shape with the outer periphery of the end face of the injection member. That is, the bottom of the cavity is formed by only the end face of the injection member.

Therefore, the lower end face of the semiconductor device can be formed into a smooth shape without undulations by using a flat end face of the injection member.

In one embodiment of the present invention, The semiconductor device manufacturing apparatus as set forth in claim 6, wherein

the lower metal mold has a plurality of the cavities, and

communication passages, through which all the cavities communicate at least in series with one another, are formed on mutually facing surfaces of the upper and lower metal molds when the upper and lower metal molds contact with each other.

According to the embodiment, when the upper and lower metal molds contact with each other, the communication passages is formed on the mutually facing surfaces of the upper and lower metal molds, so that through the communication passages all the cavities communicate with one another at least in series. Therefore, the resin of the cavity moves via the communication passages even if variation occurs in the amount of the resin to be charged in the cavities, and the variation in the amount of the resin of the cavities can be suppressed. Therefore, it is possible to manufacture a semiconductor device in a stable shape.

In one embodiment of the present invention, The semiconductor device manufacturing apparatus as set forth in claim 6, wherein

a subcavity, which communicates with the cavity of the lower metal mold, is formed on mutually facing surfaces of the upper and lower metal molds when the upper and lower metal molds contact with each other.

According to the embodiment, when the upper and lower metal molds contact with each other, the subcavity is formed on the mutually facing surfaces of the upper and lower metal molds and communicate with the cavity of the lower metal mold. Therefore, even if the resin is excessively injected into the cavity, the superfluous resin flows into the subcavity, and it is possible to manufacture a semiconductor device in a stable shape.

### BRIEF DESCRIPTION OF THE DRAWINGS

The present invention will become more fully understood from the detailed description given hereinbelow and the accompanying drawings which are given by way of illustration only, and thus are not limitative of the present invention, and wherein:

FIG. 1A shows a schematic sectional view of a semiconductor device manufacturing apparatus according to a first embodiment of the present invention, and a first step of a semiconductor device manufacturing method with use of the manufacturing apparatus;

FIG. 1B shows a schematic sectional view of a second step of the semiconductor device manufacturing method with use of the manufacturing apparatus of the first embodiment;

FIG. 1C shows a schematic sectional view of a third step of the semiconductor device manufacturing method with use of the manufacturing apparatus of the first embodiment;

FIG. 1D shows a schematic sectional view of a fourth step of the semiconductor device manufacturing method with use of the manufacturing apparatus of the first embodiment;

FIG. 1E shows a schematic sectional view of a fifth step of the semiconductor device manufacturing method with use of the manufacturing apparatus of the first embodiment;

FIG. 2A shows a schematic sectional view of a semiconductor device manufacturing apparatus according to a second embodiment of the present invention;

FIG. 2B shows a schematic sectional view of a first step of a semiconductor device manufacturing method with use of the manufacturing apparatus of the second embodiment;

FIG. 2C shows a schematic sectional view of a second step of the semiconductor device manufacturing method with use of the manufacturing apparatus of the second embodiment;

FIG. 3 shows a schematic sectional view of a semiconductor device manufacturing apparatus according to a third embodiment of the present invention and a semiconductor device manufacturing method with use of the manufacturing apparatus;

FIG. 4A shows a schematic sectional view of a semiconductor device manufacturing apparatus according to a fourth embodiment of the present invention and a semiconductor device manufacturing method with use of the manufacturing apparatus;

FIG. 4B shows a schematic sectional view of a semiconductor device manufactured by using the manufacturing apparatus and the manufacturing method of the fourth embodiment;

FIG. 5A shows a schematic sectional view of the semiconductor device manufacturing apparatus according to a fifth embodiment of the present invention and a first step of a semiconductor device manufacturing method with use of the manufacturing apparatus;

FIG. 5B shows a schematic sectional view of the second step of the semiconductor device manufacturing method with use of the manufacturing apparatus of the fifth embodiment;

FIG. 5C shows a schematic sectional view of the third step of the semiconductor device manufacturing method with use of the manufacturing apparatus of the fifth embodiment;

FIG. 6A shows a schematic sectional view of a sixth embodiment of the semiconductor device manufacturing apparatus and a semiconductor device manufacturing method with use of the manufacturing apparatus;

FIG. 6B shows a schematic sectional view of the semiconductor device manufactured with use of the manufacturing apparatus and the manufacturing method of the sixth embodiment;

FIG. 7A shows a schematic sectional view of a seventh embodiment of the semiconductor device manufacturing apparatus and the first step of a semiconductor device manufacturing method with use of the manufacturing apparatus;

FIG. 7B shows a schematic sectional view of the second step of the semiconductor device manufacturing method with use of the manufacturing apparatus of the seventh embodiment;

FIG. 8A shows a schematic sectional view of an eighth embodiment of the semiconductor device manufacturing apparatus and the first step of a semiconductor device manufacturing method with use of the manufacturing apparatus;

FIG. 8B shows a schematic sectional view of the second step of the semiconductor device manufacturing method with use of the manufacturing apparatus of the eighth embodiment;

FIG. 9 shows a schematic sectional view of a ninth embodiment of the semiconductor device manufacturing apparatus and a semiconductor device manufacturing method with use of the manufacturing apparatus;

FIG. 10A shows a schematic sectional view of a tenth embodiment of the semiconductor device manufacturing apparatus and a semiconductor device manufacturing method with use of the manufacturing apparatus;

FIG. 10B shows a schematic sectional view of the semiconductor device manufactured with use of the manufacturing apparatus and the manufacturing method of the tenth embodiment;

FIG. 11A shows a schematic sectional view of a comparative example of the semiconductor device manufacturing apparatus and a semiconductor device manufacturing method with use of the manufacturing apparatus;

FIG. 11B shows a schematic sectional view of the semiconductor device manufactured with use of the manufacturing apparatus and the manufacturing method of the comparative example;

FIG. 12A shows a schematic sectional view of an eleventh embodiment of the semiconductor device manufacturing apparatus and the first step of a semiconductor device manufacturing method with use of the manufacturing apparatus;

FIG. 12B shows a schematic sectional view of the second step of the semiconductor device manufacturing method with use of the manufacturing apparatus of the eleventh embodiment;

FIG. 13 shows a schematic sectional view of a twelfth embodiment of the semiconductor device manufacturing apparatus and a semiconductor device manufacturing method with use of the manufacturing apparatus;

FIG. 14A shows a schematic sectional view of the semiconductor device manufactured with use of the manufacturing apparatus and the manufacturing method of the twelfth embodiment;

FIG. 14B shows a schematic sectional view of the semiconductor device manufactured with use of the manufacturing apparatus and the manufacturing method of the twelfth embodiment;

FIG. 15A shows a schematic sectional view of a first step of a general manufacturing method for a semiconductor device;

FIG. 15B shows a schematic sectional view of a second step of the general manufacturing method for the semiconductor device;

FIG. 15C shows a schematic sectional view of a third step of the general manufacturing method for the semiconductor device;

FIG. 16A shows a schematic sectional view of a metal mold in one-pot type transfer molding;

FIG. 16B shows a schematic sectional view of the metal mold in multi-pot type transfer molding;

FIG. 16C shows a schematic sectional view of the metal mold in cylindrical pot type transfer molding;

FIG. 17 shows an explanatory view of a casting method; and

FIG. 18 shows an explanatory view of a potting method.

### DETAILED DESCRIPTION OF THE INVENTION

The present invention will be described in detail below by embodiments with reference to the drawings.

### First Embodiment

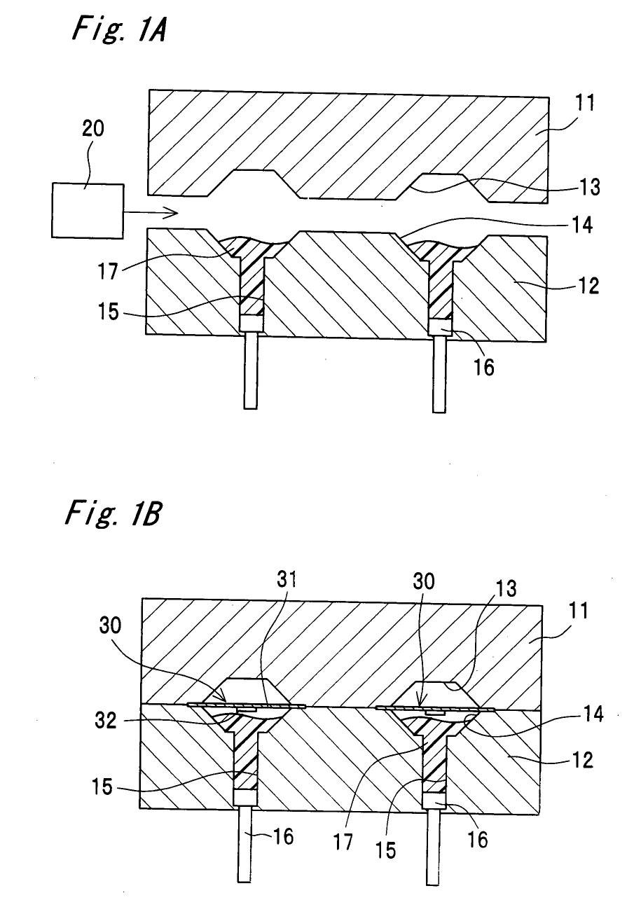

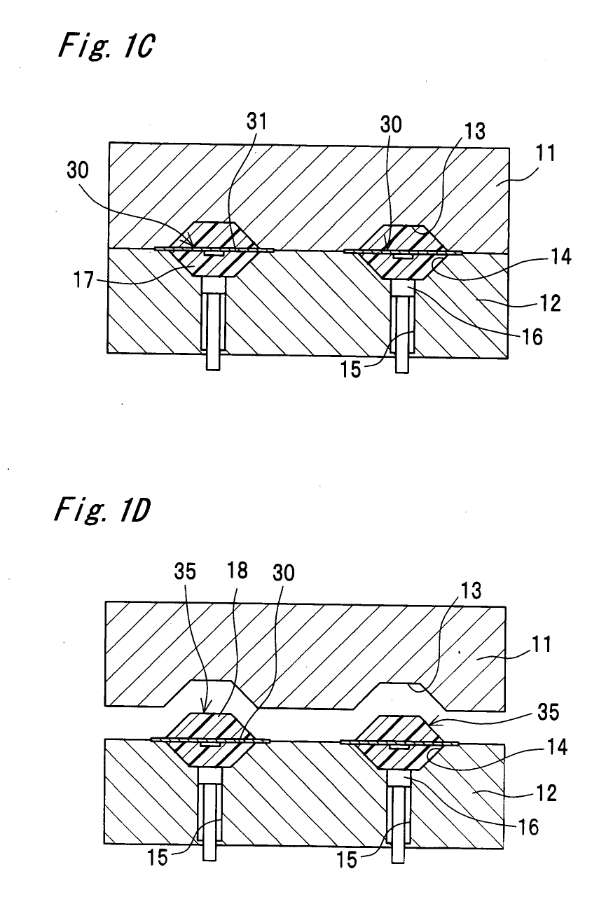

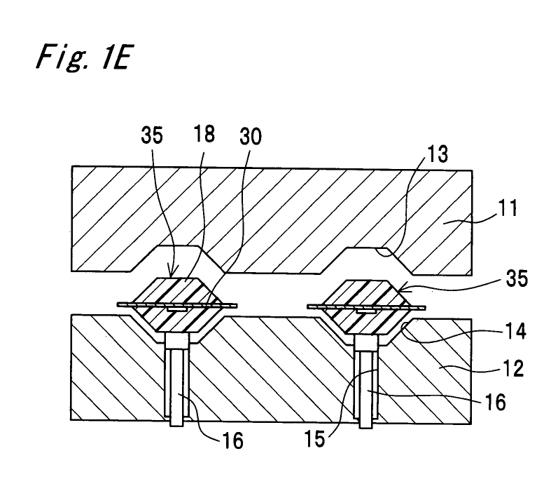

FIG. 1A shows a longitudinal sectional view of a semiconductor device manufacturing apparatus according to one embodiment of the present invention. The manufacturing apparatus has an upper metal mold 11, a lower metal mold 12 that relatively moves close to and away from the upper metal mold 11, and a filling device 20 that fills a space between the upper metal mold 11 and the lower metal mold 12 with a liquid-state resin 17.

The upper metal mold 11 has a plurality of cavities 13. The lower metal mold 12 has a plurality of cavities 14 and a resin reservoir hole 15 connected directly to each of the cavities 14. An injection member 16 is placed in the resin reservoir hole 15 so as to reciprocate therein.

The filling device 20 fills the cavities 14 and the resin reservoir hole 15 in the lower metal mold 12 with use of the liquid-state resin 17. The resin 17 is, for example, epoxy resin or silicone resin.

The upper metal mold 11 and the lower metal mold 12 cooperate to hold the semiconductor element 30 shown in FIG. 1B. The semiconductor element 30 has a lead frame 31 and a semiconductor chip 32 bonded to the lead frame 31.

The injection member 16 has a rod-like shape and extrudes the resin 17 in the resin reservoir hole 15, so that the resin 17 is injected into the cavity 14.

That is, the manufacturing apparatus manufactures the semiconductor device 35 shown in FIG. 1E by sealing the semiconductor element 30 with the liquid-state resin 17. The semiconductor device 35 has the semiconductor element 30 and a hardened resin 18 that seals at least part of the semiconductor element 30. Specifically, the hardened resin 18 seals at least the semiconductor chip 32 of the semiconductor element 30.

Next, a semiconductor device manufacturing method with use of the manufacturing apparatus of the construction is described.

As shown in FIG. 1A, the cavities 14 and the resin reservoir holes 15 of the lower metal mold 12 are filled with the liquid-state resin 17 from the filling device 20. This is conducted under a state that the upper metal mold 11 and the lower metal mold 12 are separated from each other.

Then, as shown in FIG. 1B, the semiconductor element 30 is held by the upper metal mold 11 and the lower metal mold 12. At this time, the lead frame 31 is fixed by using the upper metal mold 11 and the lower metal mold 12 in the state that the semiconductor chip 32 faces the resin reservoir hole 15.

After clamping of the upper metal mold 11 and the metal mold 12, as shown in FIG. 1C, the resin 17 in the resin reservoir holes 15 has been injected into the cavities 13 and 14 as the result of extruding the resin 17 in the resin reservoir hole 15 toward the cavities 13 and 14 by using the injection member 16. In other words, the cavities 13 and 14 are sealed with resin to which pressure is applied by the injection member 16. In addition, the volume of the resin 17 is roughly equal to a value obtained by subtracting the volume of the semiconductor element 30 from the volume of the cavities 13 and 14.

After curing the resin 17, the metal molds 11 and 12 are separated from each other as shown in FIG. 1D. The semiconductor device 35 is pushed out of the lower metal mold 12 by the injection member 16, as shown in FIG. 1E.

In the manufacturing apparatus having the above construction and the manufacturing method thereof, as stated above, the cavities 14 and the resin reservoir holes 15 of the lower metal mold 12 are filled with the liquid-state resin 17. Next, the semiconductor element 30 is held by the lower metal mold 12 and the upper metal mold 11. Then the resin 17 of the resin reservoir holes 15 is injected into the cavities 13 and 14 so as to seal the semiconductor element 30 with the resin 17. Therefore, unlike the potting method and the transfer molding method, it is possible to manufacture a semiconductor device having excellent quality with a little loss of material at low cost. The reduction in loss of material become further apparent, in particular, when silicone resin is used as the resin 17 in order to manufacture the semiconductor devices for automobiles.

In the manufacturing apparatus and method of the embodiment, the injection member 16 extrudes the resin 17 toward the cavities 13 and 14 so that the resin 17 is injected into the cavities 13 and 14. Also, the injection member 16 pushes the semiconductor element 30, which is sealed with the resin 17, out of the lower metal mold 12. Therefore, the injection member 16 is concurrently used as a plunger that extrudes the resin 17 from the resin reservoir hole 15 and as an ejector pin that pushes the semiconductor element 30 out of the lower metal mold 12. Thus the semiconductor device can be manufactured swiftly and efficiently.

Although not shown in the drawings, an air vent for letting air out is provided in the metal molds 11 and 12 in the manufacturing apparatus. In the manufacturing method, vacuum molding may be used concurrently so that the product is improved in quality.

### Second Embodiment

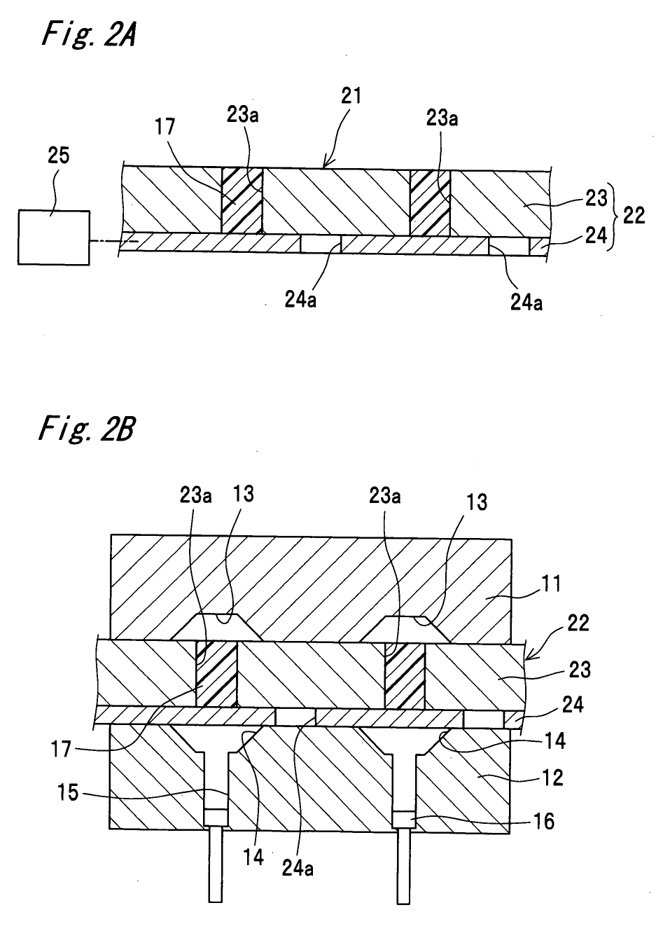

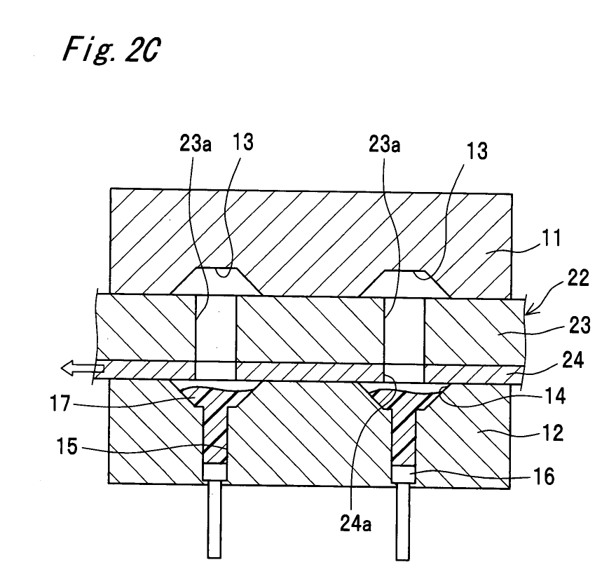

FIG. 2A shows a semiconductor device manufacturing apparatus according to a second embodiment of the present invention. The second embodiment is different from the first embodiment in construction of the filling device.

As shown in FIG. 2A, a filling device 21 of the second embodiment has a filling jig 22 and an opening and shutting device 25. The filling jig 22 has a jig main body 23 and a gate section 24. In the jig main body 23, resin injection holes 23a are formed. The gate section 24 openably closes the resin injection holes 23a. The resin injection holes 23a are filled with the liquid-state resin 17. Holes 24a are formed in the gate section 24. The opening and shutting device 25 moves the gate section 24 so that the holes 24a of the gate section 24 are aligned with the resin injection holes 23a of the jig main body 23, so as to open the resin injection holes 23a.

A method for filling the resin 17 by the filling device 21 is described next.

As shown in FIG. 2B, the filling jig 22 is placed on the lower metal mold 12 so that the resin injection holes 23a, which are filled with the resin 17, are aligned with the cavities 14 of the lower metal mold 12. At this time, the filling jig 22 is inserted and fixed between the upper metal mold 11 and the lower metal mold 12.

Then, as shown in FIG. 2C, the gate section 24 is slid to open, so that the resin reservoir holes 15 and the cavities 14 are filled with the resin 17 moved from the resin injection holes 23a through the holes 24a.

Thus, the cavities 14 and the resin reservoir holes 15 are filled with the liquid-state resin 17 from the filling jig 22, and therefore it is possible to simply and reliably fill the cavities 14 and the resin reservoir holes 15 with the liquid-state resin 17.

### Third Embodiment

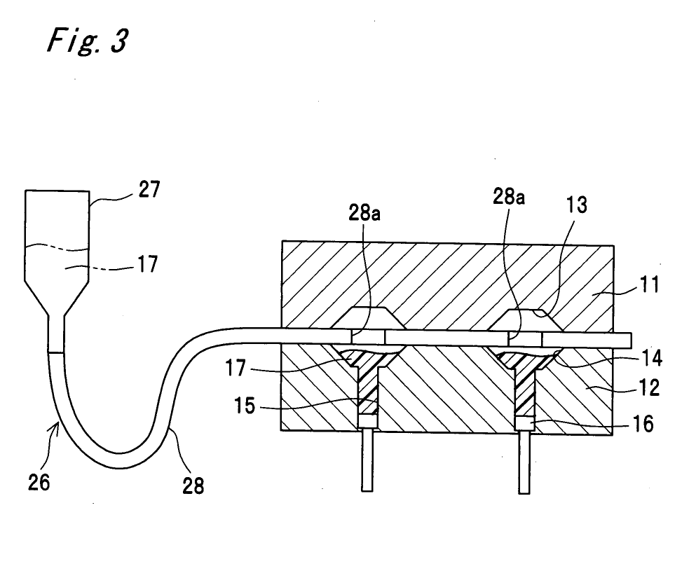

FIG. 3 shows a semiconductor device manufacturing apparatus according to a third embodiment of the present invention. The third embodiment is different from the first embodiment in construction of the filling device.

As shown in FIG. 3, a filling device 26 of the third embodiment has a syringe-shaped resin feeder 27 and a tube 28 that extends from the resin feeder 27. The resin feeder 27 is filled with the liquid-state resin 17. Openings 28a are formed in the tube 28.

A method for filling the resin 17 by the filling device 26 is described next.

The tube 28 is placed on the lower metal mold 12 in such a way that the openings 28a of the tube 28 are aligned with the cavities 14 of the lower metal mold 12. At this time, the tube 28 is inserted and fixed between the upper metal mold 11 and the lower metal mold 12.

Then, the cavities 14 and the resin reservoir holes 15 are filled with the resin 17 through the openings 28a of the tube 28 from the resin feeder 27.

Thus, the cavities 14 and the resin reservoir holes 15 are filled with the liquid-state resin 17 from the resin feeder 27 via the tube 28, and therefore it is possible to simply and reliably fill the cavities 14 and the resin reservoir holes 15 with the liquid-state resin 17.

### Fourth Embodiment

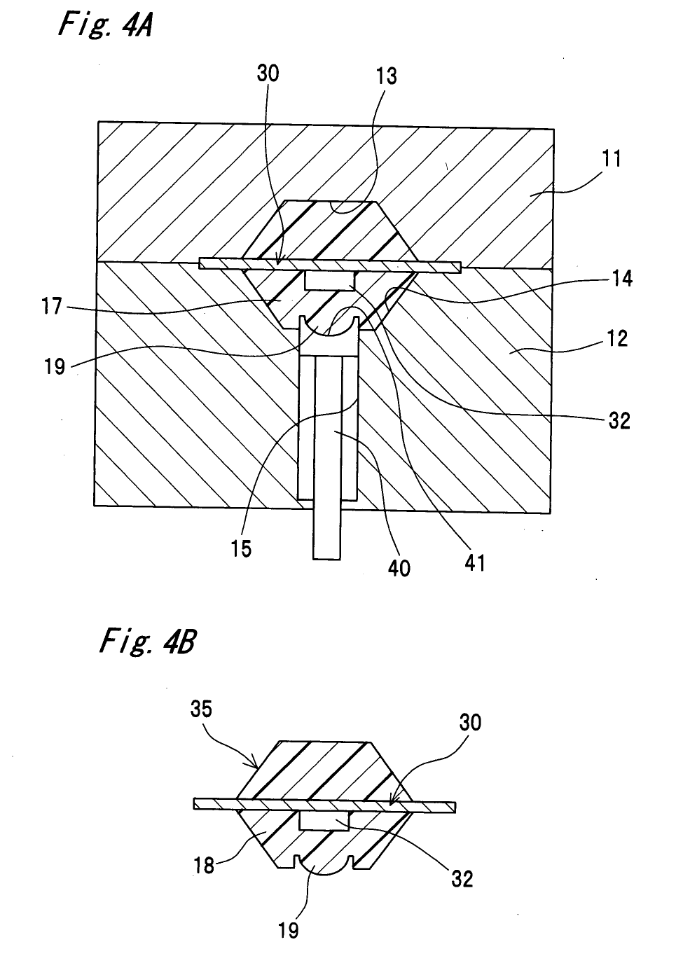

FIG. 4A shows a semiconductor device manufacturing apparatus according to a fourth embodiment of the present invention. The fourth embodiment is different from the first embodiment in construction of the injection member.

In the fourth embodiment, as shown in FIG. 4A, the injection member 40 has an end face 41 is formed into a lens-like shape. Specifically, the end face 41 of the injection member 40 is formed into a concave lens-like shape as shown on the side of the cavity 14 of the lower metal mold 12 in FIG. 4A.

Then, a method for manufacturing the semiconductor device by using the injection member 40 is explained. The resin 17 of the resin reservoir holes 15 is extruded into the cavity 14 by the injection member 40 so that the resin 17 is injected into the cavity 14. A lens portion 19 of the resin 18 is formed by the end face 41 of the injection member 40 while the resin 17 is pressurized and hardened.

That is to say, as shown in FIG. 4B, the convex lens-shaped lens portion 19 is formed on the outer surface of the hardened resin 18, which outer surface is facing the semiconductor chip 32 of the semiconductor element 30, in the semiconductor device 35 manufactured by the injection member 40.

Thus, since the end face 41 of the injection member 40 is formed into a lens-like shape, it is required to polish only the end face 41 of the injection member 40 but not the whole of the metal molds 11 and 12. This therefore leads to cost reductions of the metal molds 11 and 12. Moreover, it is possible to easily change dimensions of the lens because the injection member 40 can easily be replaced.

Moreover, it is possible to swiftly and easily form the lens portion 19 on the hardened resin 18 because the lens portion 19 is formed by pressurizing the resin 17 during the hardening process of the resin 17 with use of the end face 41 of the injection member 40 formed into a lens-like shape.

### Fifth Embodiment

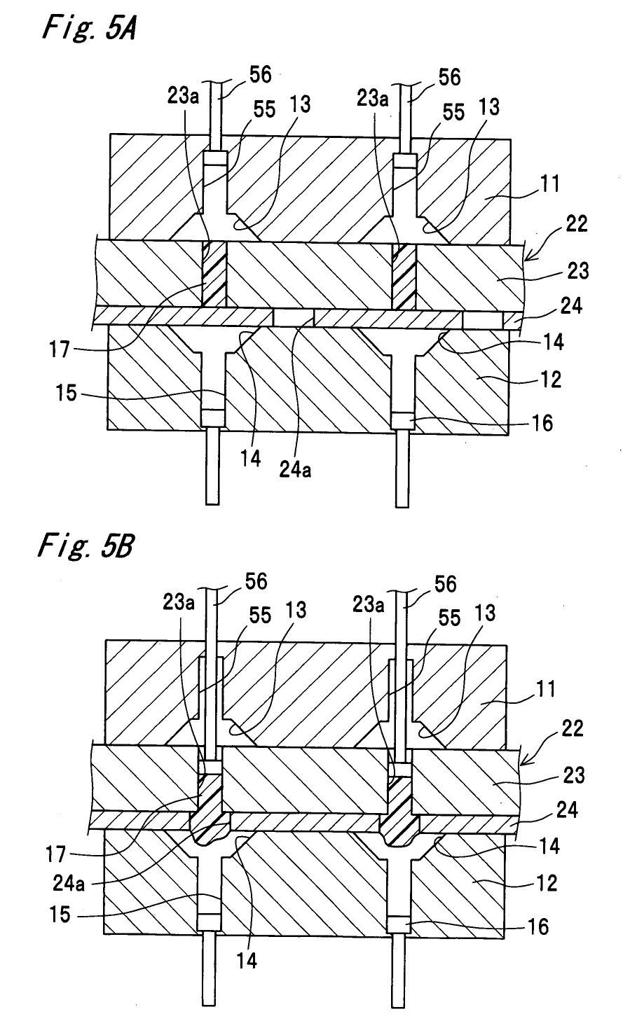

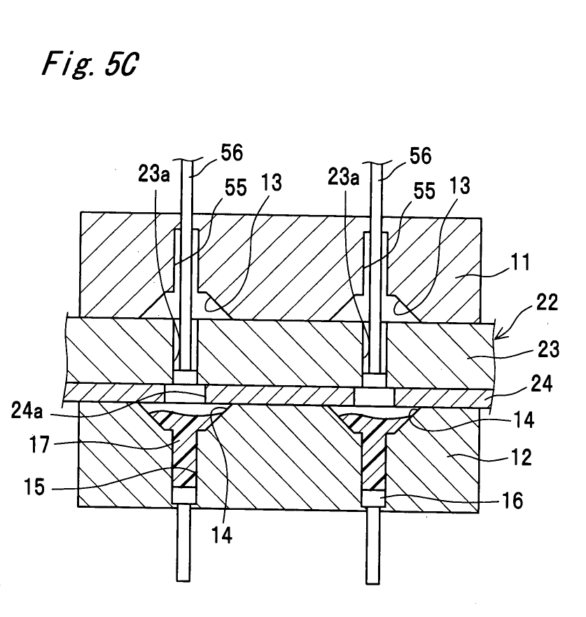

FIG. 5A shows a semiconductor device manufacturing apparatus according to a fifth embodiment of the present invention. The fifth embodiment is different from the second embodiment (FIG. 2B) in construction of the upper metal mold. The other structures are the same as those of the second embodiment, and description thereof is omitted.

In the fifth embodiment, as shown in FIG. 5A, the upper metal mold 11 has a guide hole 55 connected directly to each cavity 13. An injection member 56 is provided so that it reciprocates in the guide hole 55. The injection member 56 has a rod shape similar to that of the injection member 16 placed in the lower metal mold 12.

A semiconductor device manufacturing method with use of the manufacturing apparatus is described next.

As shown in FIG. 5A, the filling jig 22 is placed on the lower metal mold 12 in such a way that the resin injection holes 23a filled with the resin 17 are aligned with the cavities 14 of the lower metal mold 12. At this time, the filling jig 22 is inserted and fixed between the upper metal mold 11 and the lower metal mold 12.

Then, as shown in FIG. 5B, the gate section 24 is slid to open, and then the injection members 56 placed in the upper metal mold 11 is moved along the resin injection holes 23a of the filling jig 22 so as to extrude the resin 17 from the resin injection holes 23a through holes 24a. As the result, as shown in FIG. 5C, the cavities 14 and the resin reservoir holes 15 are filled with the resin 17.

By the injection members 56 placed at the upper metal mold 11, the cavities 14 and the resin reservoir holes 15 are filled with the liquid-state resin 17 from the filling jig 22. Therefore, it is possible to simply and reliably fill the cavities 14 and the resin reservoir holes 15 with the liquid-state resin 17.

### Sixth Embodiment

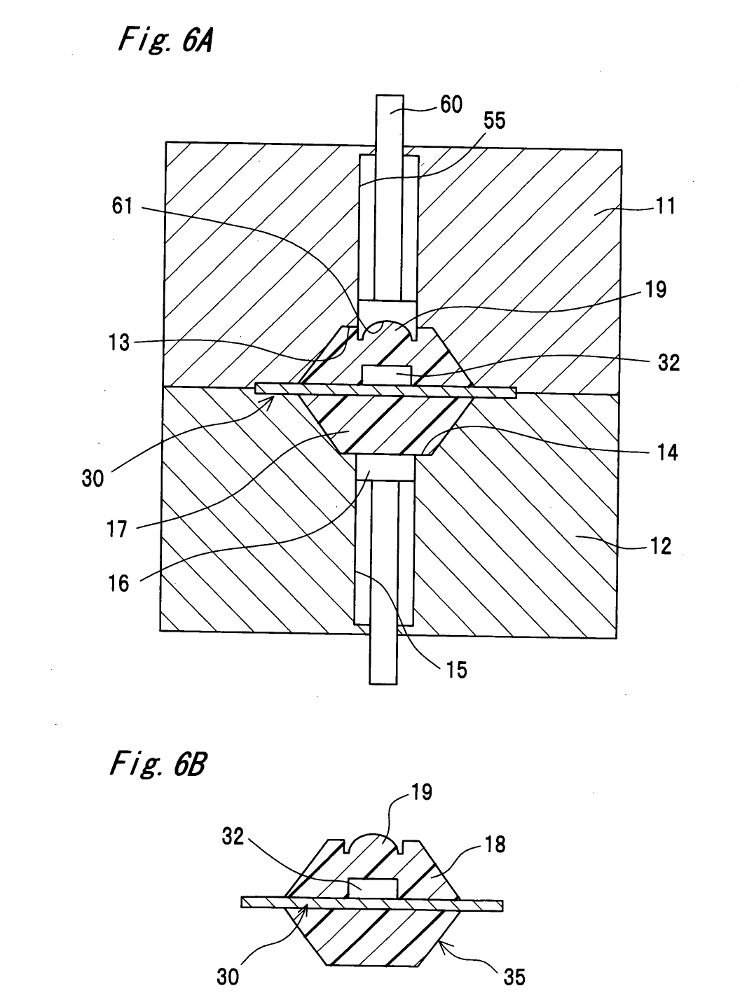

FIG. 6A shows a semiconductor device manufacturing apparatus according to a sixth embodiment of the present invention. The sixth embodiment is different from the fifth embodiment (FIG. 5A) in construction of the injection member placed at the upper metal mold.

In the sixth embodiment, as shown in FIG. 6A, an end face 61 of an injection member 60 is formed into a lens-like shape as shown on the side of the cavity 13 of the upper metal mold 11. In other words, the end face 61 is formed into a concave lens-like shape.

Then, a method for manufacturing the semiconductor device is described. The injection member 16 on the lower side extrudes the resin 17 within the resin reservoir hole 15 into the cavity 14, so that the resin 17 is injected into the cavity 14. A lens portion 19 is formed on the resin 18 during the process of hardening the resin 17 by pressurizing the resin 17 with use of the end face 61 of the injection member 60 on the upper side. It is noted that the semiconductor element 30 is arranged so that the semiconductor chip 32 faces the injection member 60 on the upper side.

That is to say, as shown in FIG. 6B, a convex lens-shaped lens portion 19 is formed on the outer surface of the hardened resin 18 in the semiconductor device 35, which outer surface is facing the semiconductor chip 32 of the semiconductor element 30.

The end face 61 of the injection member 60 on the upper side is formed into a lens-like shape, and therefore it is required to polish only the end face 61 of the injection member 60 but not the whole of the metal molds 11 and 12. This leads to cost reductions of the metal molds 11 and 12. Moreover, the injection member 60 on the upper side can easily be replaced, so that the dimensions of the lens can also be easily changed.

Moreover, the lens portion 19 can be swiftly and easily formed on the hardened resin 18 since the lens portion 19 is formed by pressurizing the resin 17 during the hardening process of the resin 17 with use of the end face 61 of the injection member 60, which is formed into a lens-like shape on the upper side.

### Seventh Embodiment

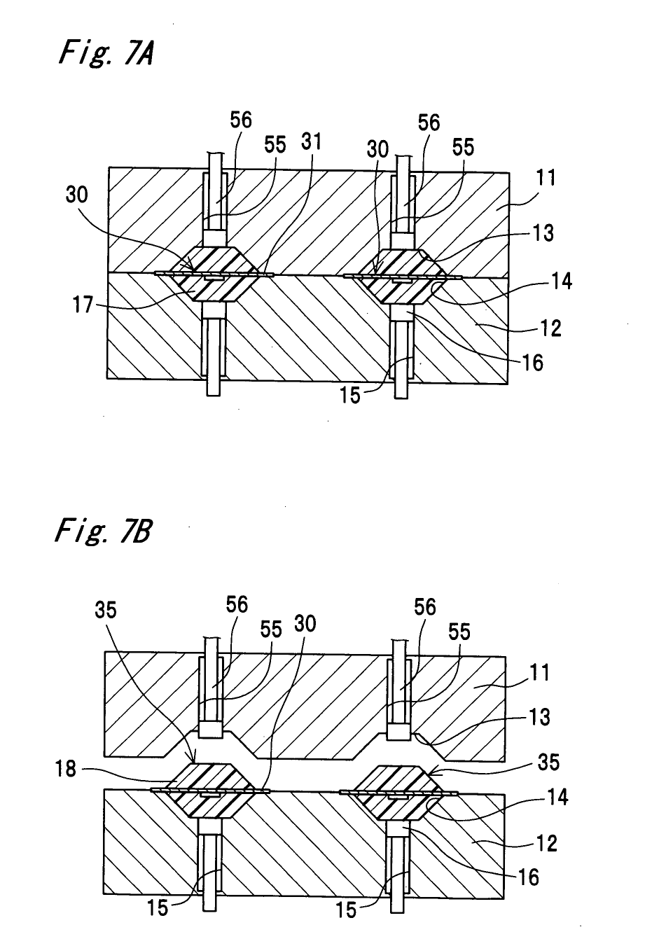

FIG. 7A shows a semiconductor device manufacturing apparatus according to a seventh embodiment of the present invention. The seventh embodiment is different from the fifth embodiment (FIG. 5A) in that the injection members 56 placed in the upper metal mold 11 are used for pushing the semiconductor devices 35 out of the cavities 13 of the upper metal mold 11.

Specifically, as shown in FIG. 7A, after clamping of the upper metal mold 11 and the lower metal mold 12, the resin 17 of the resin reservoir holes 15 is extruded into the cavities 13 and 14 by suing the injection member 16 on the lower side, so that the resin 17 is injected into the cavities 13 and 14. Then, resin sealing in the cavities 13 and 14 is performed by applying pressure to the resin 17 with use of both the injection members 56 on the upper side and the injection members 16 on the lower side.

Then, after the resin 17 is hardened, as shown in FIG. 7B, the upper metal mold 11 and the lower metal mold 12 are relatively separated from each other while the injection member 56 on the upper side pushes the semiconductor devices 35 out of the cavities 13 formed in the upper metal mold 11.

Therefore, the semiconductor devices 35 can be manufactured swiftly and efficiently because the injection member 56 on the upper side is served as not only a plunger that extrudes the resin 17 from the filling jig 22 (as in the case of the fifth embodiment) but also an ejector pin that pushes the semiconductor device 35 out of the upper metal mold 11.

### Eighth Embodiment

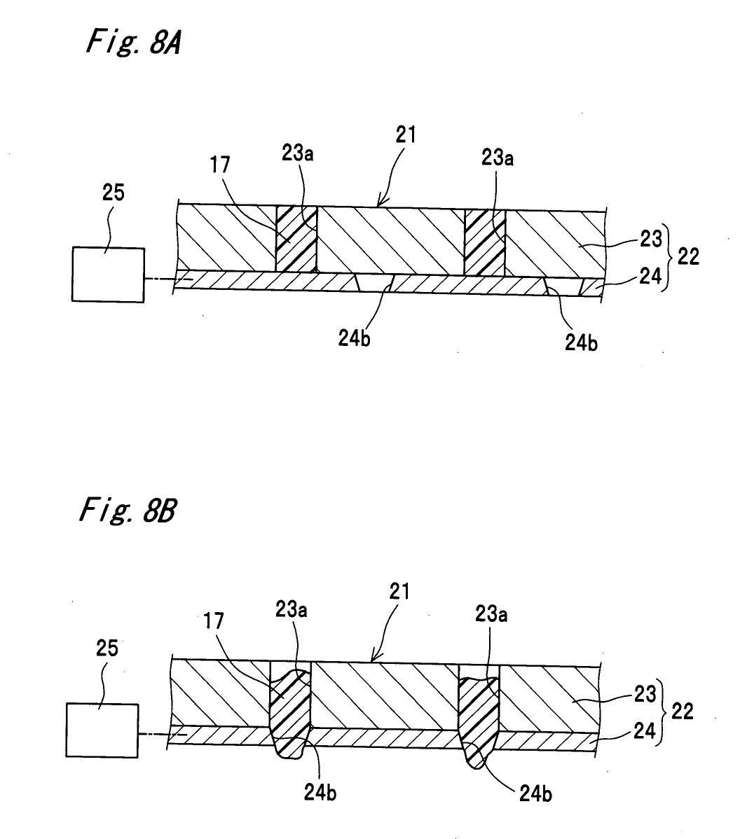

FIG. 8A shows a semiconductor device manufacturing apparatus according to an eighth embodiment of the present invention. The eighth embodiment is different from the second embodiment (FIG. 2A) in the shape of a hole 24b in the gate section 24 of the filling jig 22.

Specifically, the hole 24b of the gate section 24 in the filling jig 22 is tapered so that the diameter thereof gradually decreases toward the lower metal mold 12, wherein the resin 17 passes through the hole 24b from the resin injection holes 23a of the filling jig 22 when the lower metal mold 12 is filled with the resin 17.

Therefore, as shown in FIG. 8B, the holes 24b of the gate section 24 allows the resin 17 existing in the resin injection holes 23a to smoothly fill the cavity 14 of the lower metal mold 12.

### Ninth Embodiment

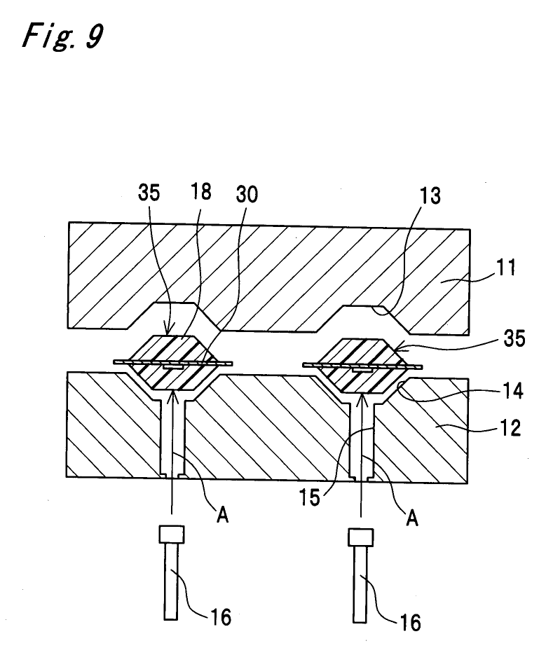

FIG. 9 shows a semiconductor device manufacturing apparatus according to a ninth embodiment of the present invention. The ninth embodiment is different from the first embodiment (FIG. 1E) in that the semiconductor devices 35 are pushed out of the lower metal mold 12 by air from the resin reservoir holes 15 of the lower metal mold 12.

Specifically, as in the case of the first embodiment (FIG. 1C), the resin 17 in the resin reservoir holes 15 is extruded into the cavities 13 and 14 by the injection members 16 so that the resin 17 is injected into the cavities 13 and 14

Subsequently, after the resin 17 is hardened, the injection members 16 are retreated from the cavity 14 as shown in FIG. 9. Then, the semiconductor devices 35 are pushed out of the lower metal mold 12 by discharging air from the resin reservoir holes 15 toward the cavities 14 (as indicated by the arrows A in FIG. 9).

Therefore, the semiconductor devices 35 can easily be taken out of the lower metal mold 12 since the semiconductor devices 35 are pushed out of the lower metal mold 12 by air from the resin reservoir holes 15.

### Tenth Embodiment

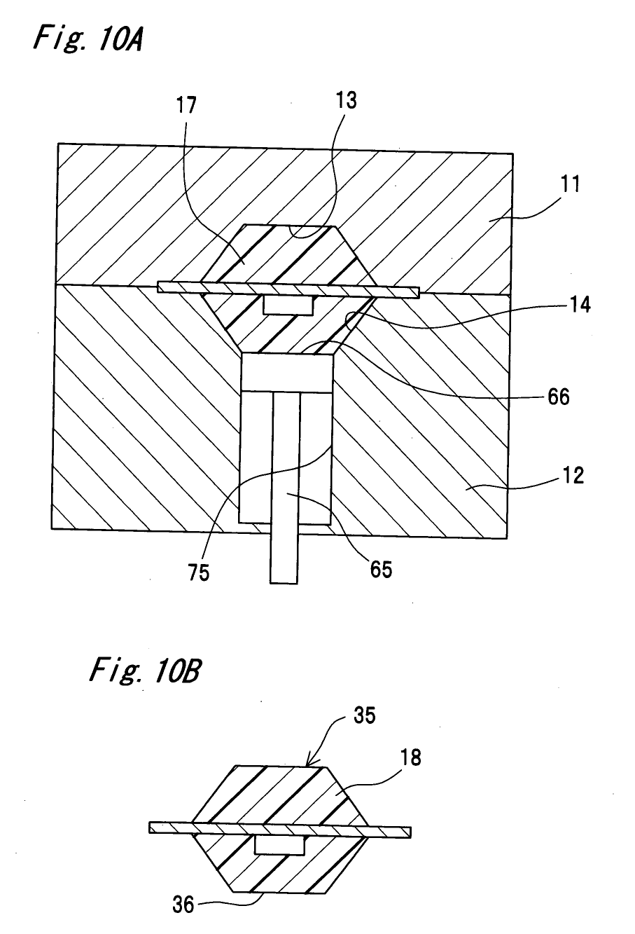

FIG. 10A shows a semiconductor device manufacturing apparatus according to a tenth embodiment of the present invention. The tenth embodiment is different from the first embodiment (FIG. 1C) in that the bottom of the cavity 14 of the lower metal mold 12 is formed by only the end face 66 of the injection member 65 on the lower side.

In detail, the outer periphery of the bottom of the cavity 14 coincides in shape with the inner periphery of the resin reservoir hole 75. The outer periphery of the end face 66 of the injection member 65 on the side of cavity 14 coincides in shape with the inner periphery of the resin reservoir hole 75.

Therefore, as shown in FIG. 10B, the lower end face 36 of the semiconductor device 35 is formed by only the end face 66 of the injection member 65, so that the lower end face 36 of the semiconductor device 35 can be formed into a smooth shape without undulations by using the flat end face 66.

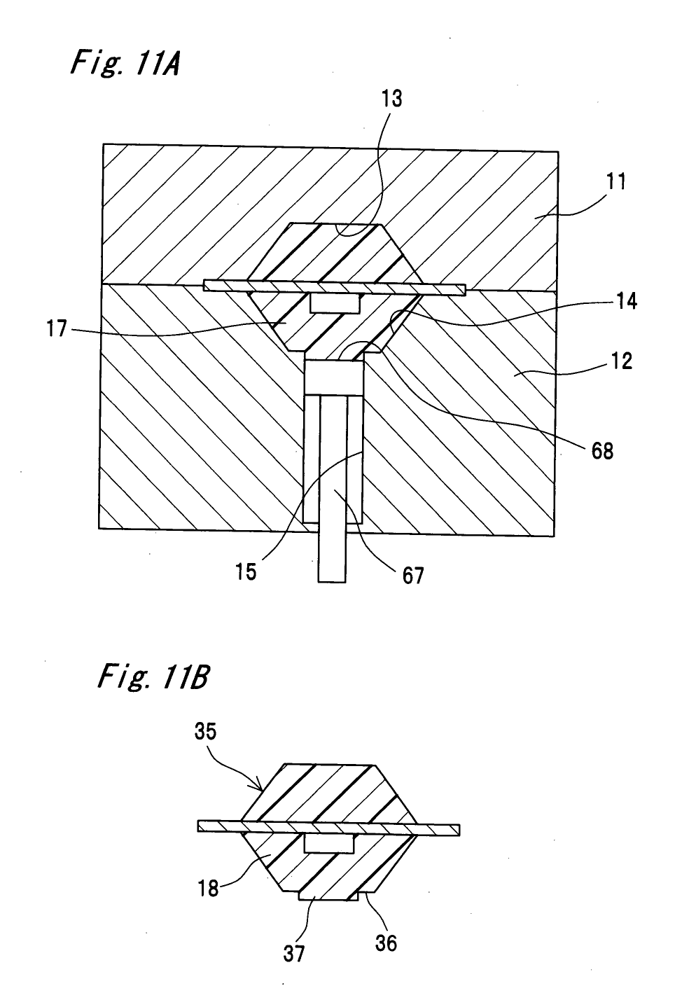

In contrast to this, as shown in FIG. 11A as a comparative example, when the shape of the bottom of the cavity 14 is not coincident with but larger than the shape of the resin reservoir hole 15, the end face 68 of the injection member 67 on the side of the cavity 14 forms a portion of the bottom of the cavity 14.

In this case, the end face 68 of the injection member 67 is located in a position lower than the other portion of the bottom of the cavity 14. When resin 17 is charged in the cavities 13 and 14, as shown in FIG. 11B, a protrusion 37 is formed on the lower end face 36 of the semiconductor device 35 by using the end face 68 of the injection member 67.

### Eleventh Embodiment

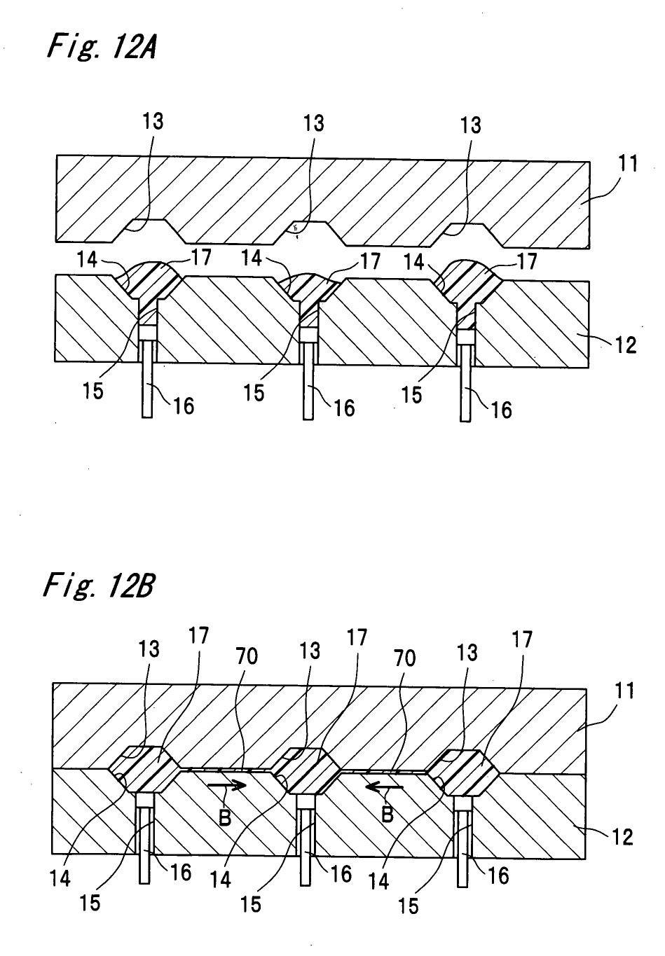

FIGS. 12A and 12B show a semiconductor device manufacturing apparatus according to an eleventh embodiment of the present invention. The eleventh embodiment is different from the first embodiment (FIG. 1B) in that communication passages 70 are provided between the upper metal mold 11 and the lower metal mold 12 so that a plurality of cavities 13 and 14 communicate with one another through the communication passages. It is noted that the semiconductor element 30 of FIG. 1B is omitted from the illustrations of FIGS. 12A and 12B.

Specifically, the upper metal mold 11 and the lower metal mold 12 have a plurality of the cavities 13 and 14, respectively. When the upper and lower metal molds 11 and 12 contact with each other, the communication passages 70 are formed on the mutually facing surfaces of the upper metal mold 11 and the lower metal mold 12, so that all the cavities 13 and 14 communicate at least in series with one another through he communication passages 70. The communication passages 70 may be formed in such a way that all the cavities 13 and 14 mutually communicate with one another.

When variation occurs in the amounts of the resin 17 charged into the cavities 14, specifically, when the amount of the resin 17 charged in the central cavity 14 is smaller than the amount of the resin 17 charged in the both end cavities 14 as shown in FIG. 12A, the resin 17 in the both end cavities 14 move into the central cavity 14 via the communication passages 70 as indicated by the arrows B as shown in FIG. 12B after the clamping of the upper metal mold 11 and the lower metal mold 12. As the result, the variation in the amount of the resin 17 in the cavities 13 and 14 can be suppressed, and therefore, semiconductor devices 35 of a stable shape can be manufactured.

### Twelfth Embodiment

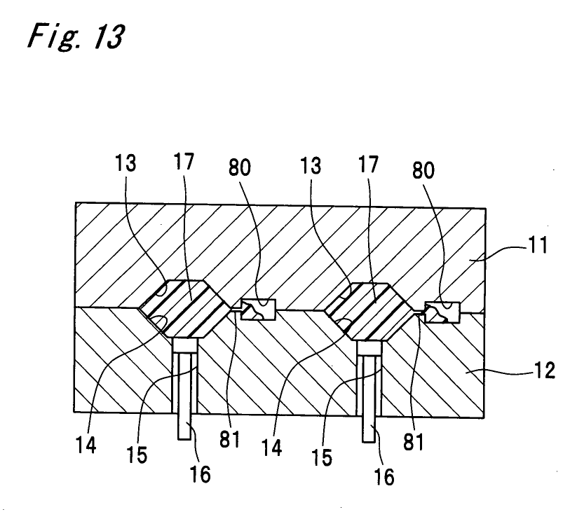

FIG. 13 shows a semiconductor device manufacturing apparatus according to a twelfth embodiment of the present invention. The twelfth embodiment is different from the first embodiment (FIG. 1B) in that subcavities 80 are formed in the upper metal mold 11 and the lower metal mold 12 so as to communicate with the cavities 13 and 14. It is noted that the semiconductor element 30 of FIG. 1B is omitted from the illustration of FIG. 13.

Specifically, when the upper metal mold 11 and the lower metal mold 12 contact with each other, the subcavities 80 for communicating with the cavities 13 and 14 are formed on the mutually facing surfaces of the upper and lower metal molds 11 and 12. The cavities 13, 14 and the subcavities 80 communicate with each other via a communication passage 81 that is formed therebetween on the mutually facing surfaces of the upper metal mold 11 and the lower metal mold 12.

Then, if the resin 17 is excessively injected into the cavity 14, the superfluous resin 17 flows from the cavity 14 into the subcavity 80, and therefore a semiconductor device 35 of a stable shape can be manufactured. Moreover, superfluous air in the cavities 13 and 14 can be sent into the subcavities 80.

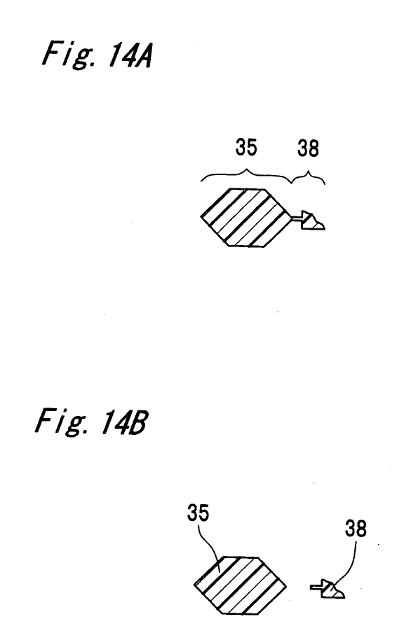

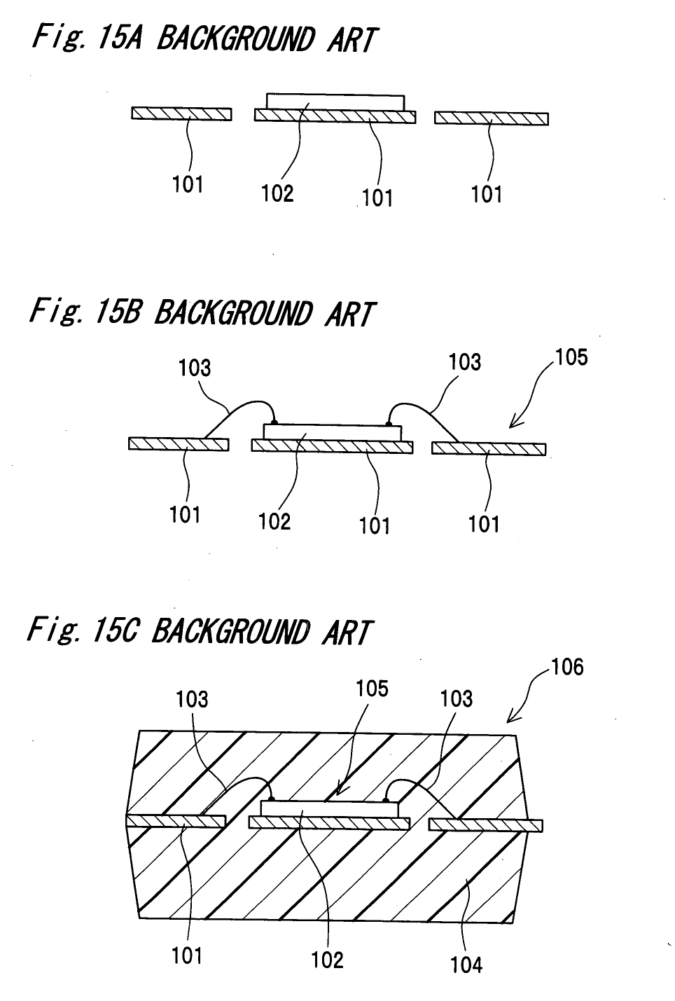

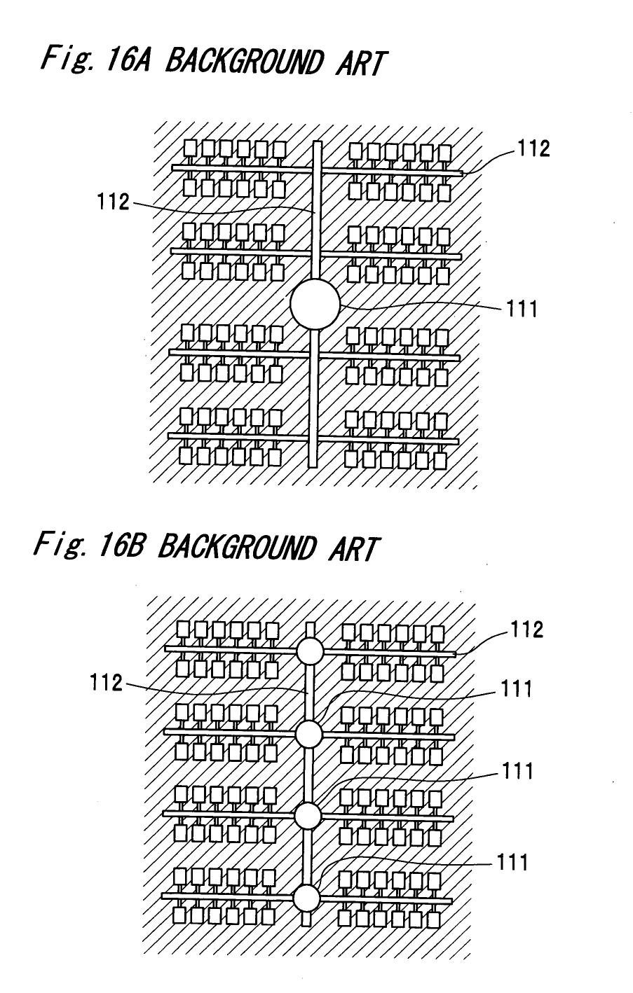

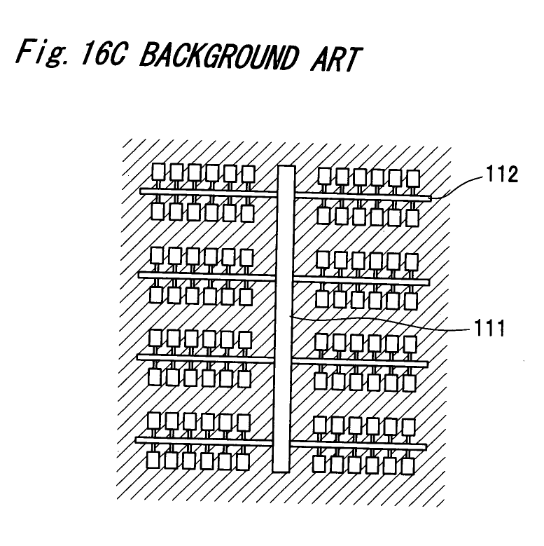

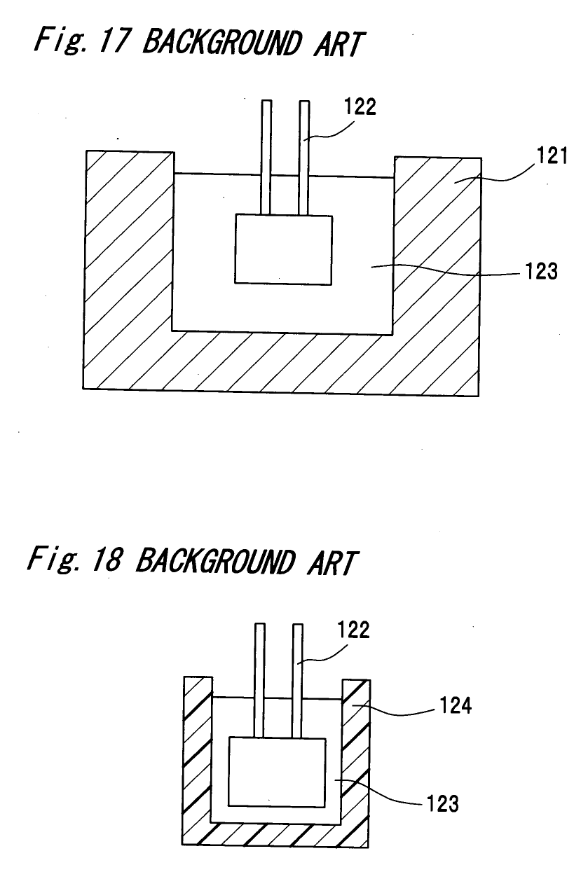

That is, the redundant portion 38 formed of the superfluous resin in the subcavity 80 is attached to the semiconductor device 35 taken out of the upper and lower metal molds 11 and 12, as shown in FIG. 14A. Therefore, the redundant portion 38 is removed from the semiconductor device 35 in a subsequent process. It is noted that the semiconductor element 30 of FIG. 1B is omitted from the illustrations of FIGS. 14A and 14B.

The invention being thus described, it will be obvious that the invention may be varied in many ways. Such variations are not be regarded as a departure from the spirit and scope of the invention, and all such modifications as would be obvious to one skilled in the art are intended to be included within the scope of the following claims.

1. A semiconductor device manufacturing method comprising:
a first step of filling a cavity formed in a lower metal mold and a resin reservoir hole formed in the lower metal mold and connected to the cavity with a liquid-state resin;
a second step of holding a semiconductor element between the lower metal mold and an upper metal mold; and
a third step of sealing the semiconductor element with the resin by injecting the resin of the resin reservoir hole into the cavity.

2. The semiconductor device manufacturing method as set forth in claim 1, wherein
the first step comprises:
placing a filling jig on the lower metal mold in such a way that a resin injection hole, which is formed in the filling jig and filled with the resin, is aligned with the cavity of the lower metal mold; and
filling the cavity and the resin reservoir hole with the resin through the resin injection hole by opening a gate section formed in the filling jig to close or open the resin injection hole.

3. The semiconductor device manufacturing method as set forth in claim 1, wherein
the first step comprises:
placing a tube extending from a resin feeder filled with the resin on the lower metal mold in such a way that an opening of the tube is aligned with the cavity of the lower metal mold; and
filling the cavity and the resin reservoir hole with the resin through the opening of the tube via the tube from the resin feeder.

4. The semiconductor device manufacturing method as set forth in claim 1, wherein
the third step comprises:
injecting the resin of the resin reservoir hole into the cavity by extruding the resin into the cavity with use of an injection member moving in the resin reservoir hole; and
pushing the semiconductor element sealed with the resin out of the lower metal mold with use of the injection member after the resin is hardened.

5. The semiconductor device manufacturing method as set forth in claim 1, wherein
the third step comprises:
injecting the resin of the resin reservoir hole into the cavity by extruding the resin into the cavity with use of an injection member moving in the resin reservoir hole; and
forming a lens portion of the hardened resin by pressurizing the resin during a hardening process with use of an end face formed in a lens-like shape of the injection member.

6. A semiconductor device manufacturing apparatus comprising:
a lower metal mold having a cavity and a resin reservoir hole directly connected to the cavity;
an upper metal mold relatively coming close to or away from the lower metal mold and holding a semiconductor element together with the lower metal mold;
a filling device filling the cavity and the resin reservoir hole in the lower metal mold with a liquid-state resin; and
an injection member placed in the resin reservoir hole so as to reciprocate in the resin reservoir hole and injecting the resin of the resin reservoir hole into the cavity by extruding the resin into the cavity with use of the injection member.

7. The semiconductor device manufacturing apparatus as set forth in claim 6, wherein
an end face of the injection member, which end face is placed on a side of the cavity in the lower metal mold, is formed into a lens-like shape.

8. The semiconductor device manufacturing method as set forth in claim 1, wherein
the first step comprises:
placing the filling jig on the lower metal mold in such a way that a resin injection hole, which is formed in the filling jig and filled with the resin, is aligned with the cavity of the lower metal mold; and
filling the cavity and the resin reservoir hole with the resin through the resin injection hole by opening a gate section formed in the filling jig to close or open the resin injection hole and by moving an injection member, which is placed in the upper metal mold, in the resin injection hole of the filling jig.

9. The semiconductor device manufacturing method as set forth in claim 8, wherein,
a lens portion of the hardened resin is formed by pressurizing the resin during hardening the resin by using an end face of the injection member placed in the upper metal mold, which end face is formed into a lens-like shape.

10. The semiconductor device manufacturing method as set forth in claim 8, wherein
the semiconductor element sealed with the resin is pushed out of the cavity formed in the lower metal mold by using the injection member placed in the upper metal mold after the resin is hardened.

11. The semiconductor device manufacturing method as set forth in claim 2, wherein
a hole of the gate section of the filling jig, via which the resin passes when the lower metal mold is filled with the resin through the resin injection hole of the filling jig, is tapered in such a way that the hole gradually decreases in diameter toward the lower metal mold.

12. The semiconductor device manufacturing method as set forth in claim 1, wherein
the third step comprises:
injecting the resin of the resin reservoir hole into the cavity by extruding the resin into the cavity with use of an injection member moving in the resin reservoir hole;
retreating the injection member from a side of the cavity after the resin is hardened; and
pushing the semiconductor element sealed with the resin out of the lower metal mold by discharging air from the resin reservoir hole toward the cavity.

13. The semiconductor device manufacturing apparatus as set forth in claim 6, wherein
an outer periphery of a bottom of the cavity coincides in shape with an inner periphery of the resin reservoir hole; and
an outer periphery of an end face of the injection member on a side of the cavity coincides in shape with the inner periphery of the resin reservoir hole.

14. The semiconductor device manufacturing apparatus as set forth in claim 6, wherein
the lower metal mold has a plurality of the cavities, and
communication passages, through which all the cavities communicate at least in series with one another, are formed on mutually facing surfaces of the upper and lower metal molds when the upper and lower metal molds contact with each other.

15. The semiconductor device manufacturing apparatus as set forth in claim 6, wherein
a subcavity, which communicates with the cavity of the lower metal mold, is formed on mutually facing surfaces of the upper and lower metal molds when the upper and lower metal molds contact with each other.
